(19) United States
(12) Patent Application Publication
(10) Pub. No.: US 2025/0209361 A1
(43) Pub. Date: Jun. 26, 2025

(54) SYSTEMS AND METHODS FOR REDUCING EFFECT OF NOISE ON SOLID STATE QUANTUM PROCESSORS

(71) Applicant: Silicon Quantum Computing Pty Limited, Kensington, New South Wales (AU)

(72) Inventors: Michelle Yvonne Simmons, Kensington, New South Wales (AU); John Martinis, Kensington, New South Wales (AU); Ludwik Kranz, Kensington, New South Wales (AU); Joris Keizer, Kensington, New South Wales (AU)

(73) Assignee: Silicon Quantum Computing Pty Limited, Kensington, New South Wales (AU)

(21) Appl. No.: 18/849,827

(22) PCT Filed: Mar. 23, 2023
(86) PCT No.: PCT/AU2023/050212

§ 371 Date: Sep. 23, 2024

(30) Foreign Application Priority Data
Mar. 24, 2022 (AU) 2022900741

(51) Int. Cl. G06N 10/40; H10N 60/01; H10N 60/10; H10N 69/00

(52) U.S. Cl. CPC G06N 10/40; H10N 60/01; H10N 60/10; H10N 69/00

(57) ABSTRACT

Systems and method for reducing effect of high energy radiation or charge noise on solid state quantum processors are disclosed. According to an aspect of the present disclosure, a quantum computing system is provided that includes: a semiconductor substrate, comprising a bulk layer and a qubit layer and a dielectric forming an interface with the semiconductor substrate. One or more qubits are formed in the qubit layer. The system further includes a shielding structure formed either between the bulk layer and the qubit layer or between the qubit layer and the interface. The shielding structure configured to shield the qubit layer from electric field generated in the bulk layer due to high-energy radiation or shield the qubit layer from charge noise generated in the interface.

### TECHNICAL FIELD

Aspects of the present disclosure relate generally to quantum computing, and more particularly to reducing effects of high energy radiation noise on solid state quantum processors.

Other aspects of the present disclosure relate to reducing the effects of charge noise on solid state processors.

### BACKGROUND

Quantum computers perform calculations that cannot be run by classical supercomputers, such as efficient prime factorization or solving how molecules bind using quantum chemistry. Such difficult problems can only be solved by embedding the algorithm in a large quantum computer that is running quantum error correction. However, error correction fails when physical quantum bit (qubit) errors are large or correlated.

Quantum computers have intrinsic errors, so algorithms can be natively run with typically only a few hundred to thousand logic operations. To run the most powerful and useful algorithms (e.g., with millions to billions of logic gates), errors should be reduced to a parts per million or billion range, or lower. This is possible using quantum error correction. The basic idea of quantum error correction is to redundantly encode the qubit state in many physical qubits, in a way similar to classical error correction, so that errors in the physical qubit states can be selectively measured, decoded, and corrected. For example, the surface code error correction scheme encodes a protected “logical” state with about 1000 physical qubits. If physical errors are small (about 0.1%) and occur randomly and independently among these 1000 qubits, then the logical error can be less than 0.1 part per billion. But if errors are large or correlated, occurring in bunches either together in time or together across the chip in space, then error correction fails. When the logical errors are large, the memory of the quantum computer is lost, and the algorithm fails.

Accordingly, it is desirable to reduce large or correlated errors in quantum computers.

### SUMMARY

According to an aspect of the present disclosure, there is provided a quantum computing system comprising: a semiconductor substrate, comprising a bulk layer and a qubit layer; one or more qubits formed in the qubit layer; and a shielding structure formed between the bulk layer and the qubit layer, the shielding structure configured to shield the qubit layer from electric field generated in the bulk layer due to high-energy radiation.

The shielding structure is also configured to recombine, absorb or extract electron-hole pairs created in the bulk layer due to high-energy radiation.

In some embodiments, the shielding structure includes a single layer of an n-type semiconductor. Further, in some examples, the n-type semiconductor is phosphorus doped silicon. In such examples, the concentration of dopant in the n-type semiconductor is between approximately 30% and 50%.

In some embodiments, the thickness of the shielding structure is in the range of 10 nanometers to 500 nanometers.

In some other embodiments, the shielding structure includes a plurality of layers of n-type semiconductor material interspersed with one or more spacer layers of an intrinsic silicon material. In such embodiments, the shielding structure includes anywhere between 2 to 50 layers of n-type semiconductor material. The thickness of each shielding layer may be between 10 to 500 nanometers.

In some embodiments, the shielding structure further comprises an electrode disposed at the bottom of the bulk layer, the electrode negatively charged to attract holes of the electron-hole pairs.

In some other embodiments, the shielding structure further comprises a metal plate disposed at the bottom of the bulk layer to attract holes of the electron-hole pairs.

According to another aspect of the present disclosure, there is provided a method of fabricating a quantum processing device. The method comprises: preparing a bulk layer of a semiconductor substrate; preparing a clean crystal surface of the bulk layer; exposing the clean crystal surface of the bulk layer to dopant molecules comprising a layer of dopant molecules on the exposed surface; annealing the exposed surface to incorporate at least some dopant atoms of the dopant molecules into the semiconductor to form a ground plane; and preparing a qubit layer, the qubit layer formed of isotopically inert silicon and comprising a plurality of qubits.

In some embodiments, producing the ground plane further comprises preparing multiple layers of ground planes interspersed with one or more spacer layers of undoped semiconductor.

The ground plane may be 10 nanometers to 500 nanometers in thickness and the dopant may be any one of phosphorus or aluminum. Further, the concentration of the dopant atoms in the ground plane may be between 30% and 50%.

In some embodiments, the fabrication method further comprises the step of adding a negatively charged electrode at the bottom of the bulk layer. In other embodiments, the fabrication method may further include the step of disposing a metal plate at the bottom of the bulk layer.

According to yet another aspect of the present disclosure, there is provided a quantum processor comprising: a semiconductor substrate including a qubit layer; a dielectric material forming an interface with the semiconductor substrate; one or more qubits formed in the qubit layer; and a shielding structure formed between the interface and the qubit layer, the shielding structure configured to shield the qubit layer from charge noise generated in the interface between the dielectric material and the semiconductor substrate.

In some embodiments, the shielding structure includes a single layer of an n-type semiconductor. In other embodiments, the shielding structure comprises a plurality of layers of n-type semiconductor material interspersed with one or more spacer layers of an intrinsic silicon material.

The n-type semiconductor may be phosphorus doped silicon. In some embodiments, the concentration of phosphorus in the n-type semiconductor is between approximately 30% and 50%. Further, the thickness of the shielding structure may be in the range of 10 nanometers to 500 nanometers.

When the shielding structure includes multiple layers, it may include between two to fifty layers of n-type semiconductor material and the thickness of each shielding layer may be about 10-500 nanometers.

According to still another aspect of the present disclosure, there is provided a method of fabricating a quantum processing device. The method includes the steps of preparing a bulk layer of a semiconductor substrate; preparing a clean crystal surface of the bulk layer; preparing a qubit layer, the qubit layer formed of isotopically inert silicon and comprising a plurality of qubits; growing semiconductor layer above the qubit layer; exposing the semiconductor layer to dopant molecules to produce a layer of dopant molecules on the exposed surface; annealing the exposed surface to incorporate at least some dopant atoms of the dopant molecules into the semiconductor and form a ground plane.

Producing the ground plane may further include preparing multiple layers of ground plane interspersed with one or more spacer layers of un-doped semiconductor. In some embodiments, the ground plane is between the qubit layer and an interface formed between the semiconductor substrate and a dielectric.

The ground plane may be 1 atomic monolayer and up to 500 nanometers in thickness.

Further aspects of the present invention and further embodiments of the aspects described in the preceding paragraphs will become apparent from the following description, given by way of example and with reference to the accompanying drawings.

### BRIEF DESCRIPTION OF THE DRAWINGS

FIG. 1 is a cross-section representation of a typical quantum processor.

FIG. 2 is a cross-sectional representation of a quantum processing device with a ground plane to mitigate effects of cosmic/gamma ray events, according to an embodiment of the present disclosure.

FIG. 3 is a flowchart illustrating an example method for fabricating the quantum processing device of FIG. 2.

FIG. 4 is a cross-section representation of a quantum processing device with multiple ground planes, according to an embodiment of the present disclosure.

FIG. 5A is a cross-sectional representation of a quantum processing device with a negatively charged electrode according to some embodiments of the present disclosure.

FIG. 5B is a cross-sectional representation of a quantum processing device with a metal place according to some embodiments of the present disclosure.

FIG. 6 is a cross-sectional representation of a quantum processing device with a ground plane to mitigate effects of charge noise, according to an embodiment of the present disclosure.

FIG. 7 is a flowchart illustrating an example method for fabricating the quantum processing device of FIG. 6.

FIG. 8 is a cross-section representation of a quantum processing device with multiple ground planes, according to an embodiment of the present disclosure.

The figures depict various embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION

### Mitigating Effects of High Energy Radiation

High energy radiation such as cosmic rays naturally occur from high energy particles impinging from space to the atmosphere, where they are converted into muon particles that deeply penetrate all matter on the surface of the earth. For normal electronic devices, the effect of high energy radiation is well known. In such electronic devices, radiation creates charge carriers that move through the device and changes its electrical properties, creating both temporary (pulsed) and permanent changes.

In quantum computing chips and in particular in superconducting quantum chips it was found that high energy radiation produces large and correlated errors. When cosmic ray muons travel through a superconducting quantum chip, they deposit a large amount of energy in the substrate of the superconducting quantum processor (about 200 keV), which then briefly “heats” the chip. In presently designed superconducting quantum chips, this causes the qubits to have a short memory time (about 1-10% of normal memory time), both in space (across the entire chip) and for a long time duration (about 10 ms). The qubit errors during this event are thus so large and correlated that error correction stops working and the stored logical qubit state is destroyed. As cosmic ray muons impinge on the quantum chip every few seconds, they can render inoperable any reasonably powerful algorithm running on a superconducting quantum computer.

Some techniques have been proposed to mitigate the effects of cosmic rays on quantum chips and in particular on superconducting quantum chips. For instance, one proposed technique is to operate a quantum computer deep underground or in a specially built laboratory. However, this is not a good commercial solution. In addition, there is always natural background radiation (from decay of heavy elements like Uranium) that produces similar energy events, depositing energy into the quantum chip and destroying the qubit state. Other techniques propose shielding the quantum chip with thick lead bricks (approximately 10 cm thick) outside the cryostat to reduce external radiation effects on the quantum chip and improve the coherence times of quantum bits. Although this shielding technique may protect the chip from cosmic rays, it is not very useful in shielding against background radiation. Further, this technique would be impractical for future scalable quantum computers.

Thus, redesign of solid-state quantum chips is needed.

The inventors of the present disclosure have found that unlike superconducting qubits/processors, solid state qubits/processors are less susceptible to phonon-energy produced by background radiation events and do not suffer as much from “heat pulses” of the phonon energy. Instead, in solid-state quantum processors (such as those made using semiconductors such as silicon and/or germanium), background radiation events such as cosmic rays and gamma rays produce electron-hole pairs in the device. Over time, these electron-hole pairs get trapped and accumulate within the semiconductor substrate which leads to a charged background (also called “charge offset”). The charge offset/background charge affects qubits (e.g., during initialization, operation, and readout) and gate operations leading to correlated qubit errors. As more and more electron-hole pairs are created, this effect becomes more prominent.

Further, solid-state quantum chips require refrigeration at milliKelvin temperatures for their optimal operation. At such low temperatures, the electron-hole pairs (or charge offsets) created by cosmic/gamma ray events are even more problematic (in comparison to room temperature) because the electron-hole pairs tend to freeze out as they are less likely to move around or be able to recombine within the semiconductor substrate at such low temperatures.

Although the problem of electron-hole pairs build-up is known for classical electronic transistors at room temperatures, this has not been discussed or addressed for solid state quantum systems and it is desirable to remove correlated qubit errors caused by electron-hole build-up from solid-state quantum processors comprising a large number of qubits.

Embodiments of the present disclosure attempt to address this issue. In particular, some embodiments of the present disclosure provide a new solid-state quantum processor chip architecture that aids in reducing or eliminating the effects of cosmic, gamma or other background rays on qubits/gates of solid-state quantum processors.

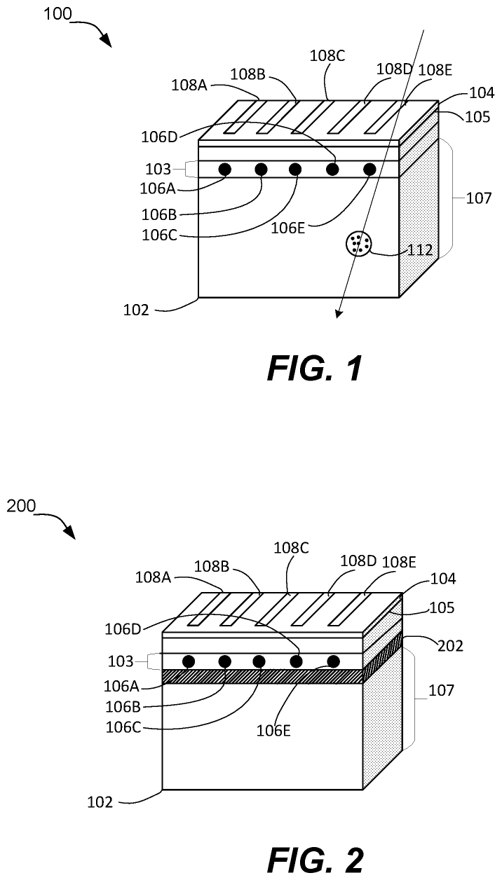

Typically, solid-state quantum processors include a semiconductor substrate, e.g., a silicon substrate. Qubits are generally positioned/fabricated in a top portion of the semiconductor substrate. FIG. 1 illustrates one such semiconductor-based quantum processing device 100. The device 100 includes a semiconductor substrate 102 and a dielectric 104. In this example, the semiconductor substrate is silicon-28 and the dielectric is silicon dioxide. In other embodiment, the semiconductor substrate may be natural silicon or isotopically purified silicon-28 or any other semiconductor material such as Germanium. The semiconductor substrate 102 and dielectric 104 form an interface 105, which in this example is a Si/SiO2 interface. Further, the device 100 includes a plurality of qubits formed in the semiconductor substrate 102 under the interface 105. In this example, the device 100 includes five qubits-106A-106E. Gates 108A-108E to control the qubits 106A-106E are fabricated on top of the dielectric 104.

The portion of the semiconductor substrate 102 in which the qubits are formed is referred to as a qubit layer 103 and the remaining portion of the semiconductor substrate is referred to as a bulk layer 107 in this disclosure. The thickness of the qubit layer 103 may depend on the qubit size, the depth from the interface 105 at which the qubits are formed, etc. It will be appreciated that the layers of the device 100 in this figure are not drawn to scale and in real implementations the layers will have very different scales. For instance, the semiconductor bulk layer to qubit layer may have a ratio of 49:1 in some examples.

Further still, although FIG. 1 and the remaining device figures in this disclosure show five qubits and five gates, the number of qubits and gates may vary significantly from these numbers in actual implementation. In some cases, the quantum processing device 100 may include 10s, 100s or even 1000s of qubits. Further still, the quantum processing device 100 may be a node of a larger quantum processor, which includes multiple such interconnected nodes 100.

As shown in FIG. 1, a cosmic/gamma ray event may create a cluster 112 of electron-hole pairs in the silicon substrate that can over time lead to correlated errors.

Typically, cosmic and gamma ray energies are in the range of about 1 MeV. When a cosmic/gamma ray event occurs in a semiconductor substrate 102 such as silicon, roughly 10% of the cosmic/gamma ray energy is utilized in creating electron-hole pairs in the silicon substrate. Creation of an electron-hole pair may take about 3.6 eV of energy, therefore, one cosmic ray event may create about 60 thousand total electron (negative charge)-hole (positive charge) pairs. These positive and negative charges are distributed randomly over the electron-hole cloud 112. If the cloud 112 has a volume of about 100 micrometer3, the density of the excitations in the cloud would be about 1 excitation every 2 micrometers.

Accordingly, average distance between an electron and a hole can be assumed to be about 1 micrometer. With these distances, the electrons and holes can create a voltage V given by—

$$V = \frac{e}{4} π ϵ d = 0.16 meV .$$

Since electrons and holes produce a negative and positive voltage respectively, the voltages randomly add in sign and magnitude with voltages further away. When random positive and negative voltages add up, the average voltage is zero. However, the net squared voltage is proportional to the number of voltage sums. In the present example, where the voltage decreases inversely with distance, the average voltage fluctuation can be computed as an integral over all the particle voltages. In this example, the distance is approximated with a continuous distribution over a radius given by the dimensionless distance Rcloud/2d, where Rcloud is the radius of the electron hole cloud 112.

$${V}^{2} = {{\int }_{0}}^{Rcloud / 2 d} {( 0.16 meV / n )}^{2} 4 π {n}^{2} {d}_{n} ) = {( 0.16 meV )}^{2} 4 π ( R cloud / 2 d ) ,$$

For the voltage, Rcloud and d values discussed above, \sqrt{V²}=2.9 meV. Accordingly, in some examples, the charge offset voltage due to one cosmic/gamma ray event may be about 2.9 meV.

Generally speaking, a change in potential at a donor atom (of a qubit) of about 50 meV can change its charge state. The potential of the donor must be held constant (e.g., voltage stability of 5 μeV) to maintain the charge state of the qubit. This stability value is 600 times smaller than the above calculated charge offset voltage 2.9 meV generated by a cosmic/gamma rate event. Thus, this gamma or cosmic ray event would have a large effect on a qubit.

To mitigate such effects of cosmic/gamma rays in the semiconductor substrate 102, the presently disclosed solid-state quantum device is designed such that the bulk layer 107 is shielded from the effects of cosmic/gamma rays.

By shielding the bulk layer 107 (which is the thickest layer in the quantum processing device 100) a significant portion of the semiconductor 102 is protected. In case, the bulk layer to qubit layer ratio is 49:1, approximately 98% of the semiconductor 102 can be protected from the mitigating effects of high energy radiation. The qubit layer 103 is typically about 10-500 nanometers in depth (and in some embodiments can be up to 1000 nanometers deep) and as this layer is not shielded, it may be affected by the cosmic/gamma ray effects—i.e., electron-hole pairs may form in this layer. However, considering the thinness of this layer, the likelihood of cosmic/gamma ray events taking place in the qubit layer 103 is very small. Furthermore, accumulation of electron-hole pairs in this layer 103 would be limited and would not be sufficient to produce charge offsets to cause noticeable correlated errors in the quantum processing device.

FIG. 2 illustrates an example quantum processing device 200 according to some embodiments of the present disclosure.

Similar to the device 100 shown in FIG. 1, quantum processing device 200 includes a semiconductor substrate 102 and a dielectric 104. In this example, the semiconductor substrate is silicon and the dielectric is silicon dioxide. The semiconductor substrate 102 and dielectric 104 form an interface 105, which in this example is a Si/SiO2 interface. Further, the device 100 includes a plurality of qubits formed in the semiconductor substrate 102 under the interface 105. In this example, the device 100 includes five qubits-106A-106E. It is will be appreciated that this is merely an example and that in real implementation, a quantum processing device may include 100s if not 1000s of qubits. Further, the qubits may be formed using any known solid state technology. For instance, the qubits 106 may be charge based or spin based qubits—i.e., where quantum information is encoded in the charge or spin of the qubit, respectively. Examples of such qubits includes donor-based phosphorous atom qubits, silicon-MOS qubits, silicon spin qubits, ion-traps, topological qubits, gate-patterned quantum dots, gate-controlled semiconductor quantum dots, etc.

Gates 108A-108E to control the qubits 106A-106E are fabricated on top of the dielectric 104. Similar to the device shown in FIG. 1, it will be appreciated that the layers of the device 100 in this figure are not drawn to scale.

In addition, the quantum processing device 200 includes a ground plane layer 202. In some examples, the ground plane 202 may be an n-type semiconductor layer, such as an n-type silicon semiconductor that is doped with a group V element such as Phosphorus, Arsenic, or Antimony. In a preferred embodiment, the ground plane 202 is formed of phosphorous-doped silicon, which is epitaxially fabricated on the bulk layer 107 of the silicon substrate 102.

The ground plane 202 may shield the top of the silicon substrate 102 from cosmic/gamma rays coming from the environment/space. Generally speaking, even with the ground plane 202, cosmic rays enter the silicon substrate 102 from the bottom or sides of the quantum processing chip, generating electron-hole pairs in the silicon substrate. However, as the ground plane 202 is more conductive than the silicon substrate it shields the qubit layer 103 from any electric field generated by stationary or moving trapped charges in the bulk layer 107 and/or qubit layer 103.

In some examples, the thickness of the ground plane 202 is in the range of 10-50 nm. Further, an electrical connection can be made between the ground plane 202 and an electrical ground of a measurement setup used to operate the quantum processing device 200.

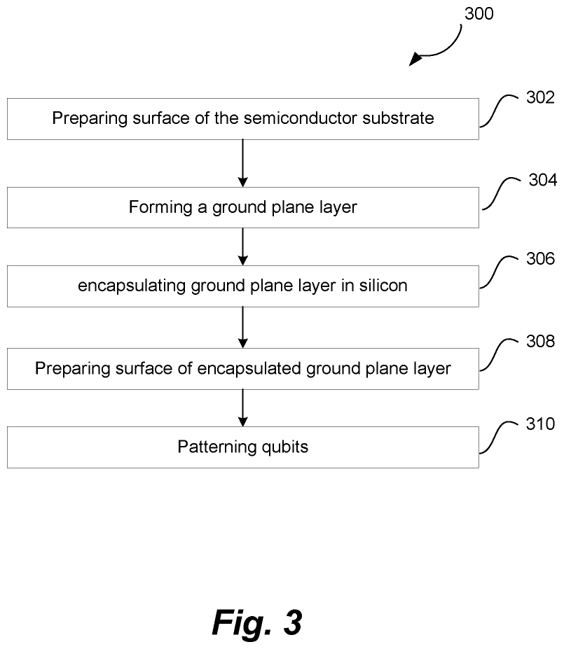

FIG. 3 is a flowchart illustrating an example manufacturing procedure for fabricating the quantum processing device 200. Method 300 describes a process for manufacturing the quantum processing device 200 with donor-atom based qubits. However, it will be appreciated that this is just one example, and the process can be implemented to manufacture a quantum processing device 200 with any other type of qubits 106 without departing from the scope of the present disclosure.

At step 302, the surface of a semiconductor substrate is prepared. In case the substrate is silicon, this step includes forming a clean silicon substrate surface in an ultra-high-vacuum (UHV) by heating to near the melting point. This surface has a 2×1 unit cell and consists of rows of σ-bonded Si dimers with the remaining dangling bond on each Si atom forming a weak π-bond with the other Si atom of the dimer of which it comprises.

Next at step 304, the ground plane is formed on top of the prepared bulk layer 107. This can be done using different techniques. For instance, in one example, the ground plane layer may be formed by ion-implantation. In another example, the ground plane layer may be formed by diffusion. In any case, the ground plane including a layer or blanket of metallic atoms (such as phosphorus or aluminum) is formed. The depth of the ground plane may be anywhere between 1 atomic monolayer to 500 nanometers. Further, the concentration of dopant may be anywhere between 20-50%.

In case the ground plane is phosphorus doped silicon, phosphine (PH3) gas is introduced into a vacuum system via a controlled leak valve connected to a specially designed phosphine dosing system. The phosphine molecule bonds strongly to the exposed Silicon 2×1 surface. Subsequent heating of the surface causes the dissociation of the phosphine molecules and results in the incorporation of phosphorus atoms into the silicon. In some embodiments, a blanket layer of phosphorus atoms may be fabricated in this manner. Additional layers of phosphorus atoms may then be fabricated-depending on the depth of the ground plane required. A similar process can be used to fabricate a ground plane doped with boron or aluminum.

Next, at step 306, the ground plane layer 202 is encapsulated with a layer of silicon. The layer of silicon may be a few 10s of nm. In one example, the ground layer 202 is encapsulated using state of the art molecular beam epitaxy. This step is called encapsulation.

At step 308, the surface of the encapsulated ground plane layer is prepared. This is similar to the process of step 302. However, this step and all following surface preparation steps are performed at lower temperatures to avoid diffusion of the dopants patterned below.

Thereafter, at step 310, the qubits 106 patterned into the silicon substrate. In particular, an STM tip is then used to selectively desorb H atoms from the passivated surface by the application of appropriate voltages and tunneling currents, forming a pattern in the H resist. In this way regions of bare, reactive Si atoms are exposed, allowing the subsequent adsorption of reactive species directly to the Si surface. Phosphine (PH3) gas is introduced into the vacuum system via a controlled leak valve connected to a specially designed phosphine micro-dosing system. The phosphine molecule bonds strongly to the exposed Silicon 2×1 surface, through the holes in the hydrogen resist. Subsequent heating of the STM patterned surface for crystal growth causes the dissociation of the phosphine molecules and results in the incorporation of P into the silicon. It is therefore the exposure of an STM patterned H passivated surface to PH3 that is used to produce the required donor atom array. The hydrogen may then be desorbed, before overgrowing with silicon at room temperature and rapidly annealing the surface. Silicon is then grown on the surface at elevated temperature.

Thereafter, a dielectric layer may be formed on the qubit layer 103. The dielectric layer may be formed by exposing the device to ambient air or by growing a dielectric layer on top of the qubit layer. Finally conductive gates 108 may be aligned on the surface in some embodiments.

In some cases, the gates can be aligned directly on a top layer of the silicon substrate of the quantum processing device 200. In such cases, a dielectric layer is not present between the silicon substrate and the gates.

Furthermore, it will be appreciated that gates 108 need not be aligned on the surface of the device in all implementations. In some implementations, the gates 108 may be ‘in-plane’ with the qubit layer 103. In such cases, the gates may be patterned at step 310.

It will be appreciated that the thickness of the layers and the distances between layers described in method 300 are merely exemplary. The actual thickness of layer and distances between layers will depend on chosen qubit technology, electron numbers, and chosen static magnetic field value for the quantum computer.

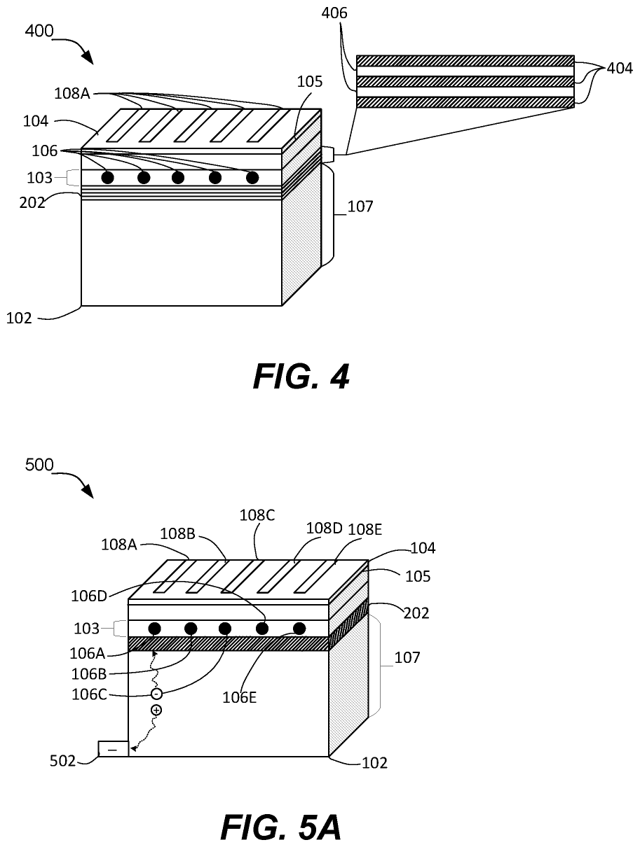

It is often difficult to fabricate a thick layer of ground plane. This is because, at high concentrations of dopant, it is difficult for the subsequent layers of the dopant to “stick to” or bond with the previous layers as the previous layers are also doped. Further, a highly concentrated thick ground plane can become electrically inactive if the dopant atoms are very close to each other. To address one or more of these issues, the ground plane can be divided. FIG. 4 shows an alternate embodiment of a quantum processing system 400. In particular, in this embodiment, instead of a single ground plane 202, the shielding structure includes a plurality of ground plane layers 404 between the bulk layer 107 and the qubit layer 103. The layers of ground plane (formed of n-type semiconductor) are separated by un-doped semiconductor spacer layers 406.

Each ground layer may be anywhere between 10-500 nanometers, where 10 nanometers represents a single layer of doped silicon and 500 nanometers represents about 50 layers of doped silicon (in case the dopant is phosphorus). Over each layer of ground plane, a spacer layer of un-doped silicon is fabricated. The thickness of the spacer layer may also be anywhere between 10-500 nanometers.

In the example shown in FIG. 4, the shielding structure includes three ground plane layers 404 interspersed by two spacer layers 406. However, in other examples, the number of ground plane layers and spacer layers may vary without departing from the scope of the present disclosure. For instance, in one embodiment, each ground plane layer may be 10 nanometers and the device may include 50 such ground plane layers interspersed with spacer layers. Further, it will be appreciated, that it is not necessary for the thickness of each ground plane layer or the concentration of dopant in each layer to be the same. There can be variations in the thickness of the ground plane layers and variation in the dopant concentrations in the various ground plane layers.

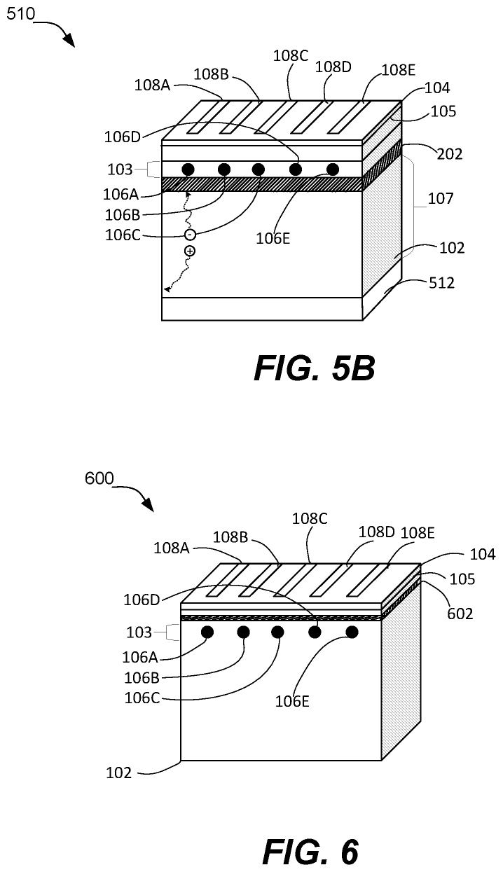

Two other variations of the quantum processing system according to embodiments of the present disclosure are shown in FIGS. 5A and 5B. FIG. 5A illustrates a quantum processing system 500, which includes a negatively charged electrode 502 positioned at the bottom of the bulk layer. The conductive ground plane (either as a single layer (as shown in FIG. 2) or as multiple layers (as shown in FIG. 3) shields the qubit layer from electric charges generated by stationary or moving charges in the bulk layer. Further, the ground plane 202, 404 attracts electrons of the electron-hole pairs from the substrate. In this example, the electrode 502 may attract holes. By including the negative electrode 502 in combination with the ground plane 202, 404 the device structure shown in FIG. 5A may be capable of absorbing/extracting the electron-hole pairs faster than the structures depicted in FIGS. 2 and 4.

In the quantum processing system 510 shown in FIG. 5B, the negatively charged electrode 502 is replaced by a metal plate 512 (e.g. copper, aluminum or any other metal). In this case, as the metal plate is more conductive than the semiconductor ground plane 202 the holes are attracted towards the metal plate 512 and the background electrons of the electron-hole pairs are repelled away from the metal plate 512 and towards the ground plane 202 and thus extracted out of the substrate 202.

Although method 300 describes a process for fabricating the quantum processing device 200 of FIG. 2, it can be used to fabricate the quantum processing devices 400, 500 and 510 of FIGS. 4, 5A and 5B respectively. For instance, to fabricate the quantum processing device 400 of FIG. 4, the method step 304 is modified such that multiple layers of ground plane 404 are grown alternatively with layers of un-doped silicon 406.

Similarly, to fabricate the quantum processing device 500 of FIG. 5A, an additional method step may be performed at the end of method 300 to add the negatively charged electrode 502 at the bottom of the bulk layer 107. Alternatively, to fabricate the quantum processing device 510 of FIG. 5B, an additional method step may be performed to dispose the metal plate 512 at the bottom of the bulk layer 107.

The above embodiments describe structures that are sufficient to channel energy of the muons away from the semiconductor bulk layer 107 and shield the qubit layer from trapped charges in the bulk layer.

### Mitigating the Effects of Charge Noise on Quantum Computers

Charge noise is another type of noise that can cause errors in quantum computers. Charge noise is typically caused by imperfections at the interface 105 between the semiconductor substrate 102 and the dielectric 104. Defects at the Si/SiO2 interface 105 or in the dielectric layer 104 can be described as bi-stable systems known as two-level fluctuators (TLFs). Each TLF has a unique Lorentzian spectrum. A random distribution of TLFs, all added together, results in 1/f noise.

Some aspects of the present disclosure attempt to address this issue. In particular, some embodiments of the present disclosure provide a new solid-state quantum processor chip architecture that aids in reducing or eliminating the effects of charge noise caused due to the interface 105 between the silicon substrate 102 and the di-electric 104 on qubits/gates of solid-state quantum processors.

To mitigate the effects of charges in the interface 105 or dielectric 104, some of the presently disclosed solid-state quantum devices are designed such that the qubit layer 103 is shielding from the interface 105 and consequently from the effects of charge noise.

FIG. 6 illustrates an example quantum processing device 600 according to some embodiments of the present disclosure.

Similar to the device 100 shown in FIG. 1, quantum processing device 600 includes a semiconductor substrate 102 and a dielectric 104. In this example, the semiconductor substrate is silicon and the dielectric is silicon dioxide. The semiconductor substrate 102 and dielectric 104 form an interface 105, which in this example is a Si/SiO2 interface. Further, the device 600 includes a plurality of qubits formed in the semiconductor substrate 102 under the interface 105. In this example, the device 600 includes five qubits—106A-106E. It is will be appreciated that this is merely an example and that in real implementation, a quantum processing device 600 may include 100s if not 1000s of qubits. Further, the qubits may be formed using any known solid state technology. For instance, the qubits 106 may be charge based or spin based qubits—i.e., where quantum information is encoded in the charge or spin of the qubit, respectively. Examples of such qubits includes donor-based phosphorous atom qubits, silicon-MOS qubits, silicon spin qubits, ion-traps, topological qubits, gate-patterned quantum dots, gate-controlled semiconductor quantum dots, etc.

Gates 108A-108E to control the qubits 106A-106E are fabricated on top of the dielectric 104. Similar to the device shown in FIG. 1, it will be appreciated that the layers of the device 100 in this figure are not drawn to scale.

In addition, the quantum processing device 200 includes a ground plane layer 602 in between the qubit layer 103 and the interface 105. In some examples, the ground plane 602 may be an n-type semiconductor layer, such as an n-type silicon semiconductor that is doped with a group V element such as Phosphorus, Arsenic, or Antimony. In a preferred embodiment, the ground plane 602 is formed of phosphorous-doped silicon, which is epitaxially fabricated between the qubit layer 103 and the interface 105.

The ground plane 602 may shield the qubit layer 103 from charge noise originating in the interface 105 or dielectric 104. In some examples, the thickness of the ground plane 602 is in the range of 10-50 nm. Further, an electrical connection may be made between the ground plane and an electrical ground of a measurement setup used to operate the quantum processing device 600.

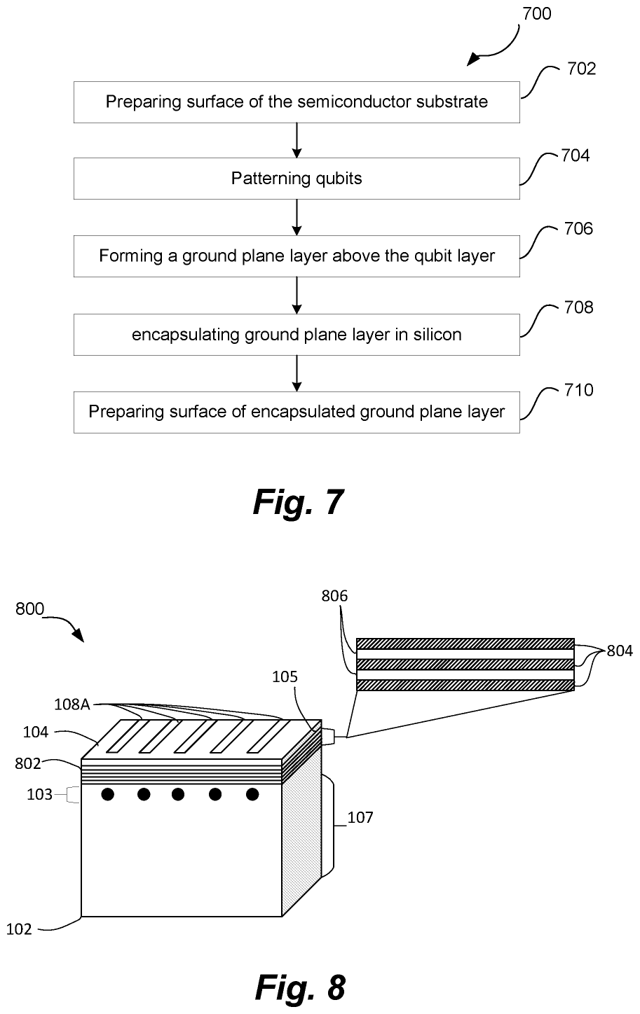

FIG. 7 is a flowchart illustrating an example manufacturing procedure for fabricating the quantum processing device 600. Method 700 describes a process for manufacturing the quantum processing device 600 with donor-atom based qubits. However, it will be appreciated that this is just one example, and the process can be implemented to manufacture a quantum processing device 600 with any other type of qubits 106 without departing from the scope of the present disclosure.

At step 702, the surface of a semiconductor substrate is prepared. In case the substrate is silicon, this step includes forming a clean silicon substrate surface in an ultra-high-vacuum (UHV) by heating to near the melting point. This surface has a 2×1 unit cell and consists of rows of σ-bonded Si dimers with the remaining dangling bond on each Si atom forming a weak π-bond with the other Si atom of the dimer of which it comprises.

Thereafter, at step 704, the qubits 106 are patterned into the silicon substrate. In particular, an STM tip is then used to selectively desorb H atoms from the passivated surface by the application of appropriate voltages and tunneling currents, forming a pattern in the H resist. In this way regions of bare, reactive Si atoms are exposed, allowing the subsequent adsorption of reactive species directly to the Si surface. Phosphine (PH3) gas is introduced into the vacuum system via a controlled leak valve connected to a specially designed phosphine micro-dosing system. The phosphine molecule bonds strongly to the exposed Silicon 2×1 surface, through the holes in the hydrogen resist. Subsequent heating of the STM patterned surface for crystal growth causes the dissociation of the phosphine molecules and results in the incorporation of P into the silicon. It is therefore the exposure of an STM patterned H passivated surface to PH3 that is used to produce the required donor atom array. The hydrogen may then be desorbed, before overgrowing with silicon at room temperature and rapidly annealing the surface. Silicon is then grown on the surface at elevated temperature. In some embodiments 10-1000 nanometers of silicon may be grown over the qubit layer 103.

Next at step 706, the ground plane 602 is formed on top of the grown silicon. This can be done using different techniques. For instance, in one example, the ground plane layer 602 may be formed by ion-implantation. In another example, the ground plane layer 602 may be formed by diffusion. In any case, the ground plane including a layer or blanket of metallic atoms (such as phosphorus or aluminum) is formed. The depth of the ground plane 602 may be anywhere between 1 atomic monolayer to 500 nanometers. Further, the concentration of dopant may be anywhere between 20-50%.

In case the ground plane 602 is phosphorus doped silicon, phosphine (PH3) gas is introduced into a vacuum system via a controlled leak valve connected to a specially designed phosphine dosing system. The phosphine molecule bonds strongly to the exposed Silicon 2×1 surface. Subsequent heating of the surface causes the dissociation of the phosphine molecules and results in the incorporation of phosphorus atoms into the silicon. In some embodiments, a blanket layer of phosphorus atoms may be fabricated in this manner. Additional layers of phosphorus atoms may then be fabricated-depending on the depth of the ground plane 602 required. A similar process can be used to fabricate a ground plane doped with boron or aluminum.

Next, at step 708, the ground plane layer 202 is encapsulated with a layer of silicon. The layer of silicon may be a few 10s of nm. In one example, the ground layer 202 is encapsulated using state of the art molecular beam epitaxy. This step is called encapsulation.

At step 710, the surface of the encapsulated ground plane layer is prepared. This is similar to the process of step 702. However, this step and all following surface preparation steps are performed at lower temperatures to avoid diffusion of the dopants patterned below.

Thereafter, a dielectric layer may be formed on the qubit layer 103. The dielectric layer may be formed by exposing the device to ambient air or by growing a dielectric layer on top of the qubit layer. Finally conductive gates 108 may be aligned on the surface in some embodiments.

In some cases, the gates can be aligned directly on a top layer of the silicon substrate of the quantum processing device 200. In such cases, a dielectric layer is not present between the silicon substrate and the gates.

Furthermore, it will be appreciated that gates 108 need not be aligned on the surface of the device in all implementations. In some implementations, the gates 108 may be ‘in-plane’ with the qubit layer 103. In such cases, the gates may be patterned at step 704 when the qubits layer 103 is formed.

The thickness of the layers and the distances between layers described in method 700 are merely exemplary. The actual thickness of the layers and the distances between the layers will depend on chosen qubit technology, electron numbers, and chosen static magnetic field value for the quantum computer.

It is often difficult to fabricate a thick layer of ground plane. This is because, at high concentrations of dopant, it is difficult for the subsequent layers of the dopant to “stick to” or bond with the previous layers as the previous layers are also doped. Further, a highly concentrated thick ground plane can become electrically inactive if the dopant atoms are very close to each other. To address one or more of these issues, the ground plane can be divided. FIG. 8 shows an alternate embodiment of a quantum processing system 800. In particular, in this embodiment, instead of a single ground plane 602, the shielding structure includes a plurality of ground plane layers 804 between the qubit layer 103 and the interface 105. The layers of ground plane (formed of n-type semiconductor) are separated by un-doped semiconductor spacer layers 806.

Each ground layer may be anywhere between 10-500 nanometers, where 10 nanometers represents a single layer of doped silicon and 500 nanometers represents about 50 layers of doped silicon (in case the dopant is phosphorus). Over each layer of ground plane, a spacer layer of un-doped silicon is fabricated. The thickness of the spacer layer may also be anywhere between 10-500 nanometers.

In the example shown in FIG. 8, the shielding structure includes three ground plane layers 804 interspersed by two spacer layers 806. However, in other examples, the number of ground plane layers and spacer layers may vary without departing from the scope of the present disclosure. For instance, in one embodiment, each ground plane layer may be 10 nanometers and the device may include 50 such ground plane layers interspersed with spacer layers. Further, it will be appreciated, that it is not necessary for the thickness of each ground plane layer or the concentration of dopant in each layer to be the same. There can be variations in the thickness of the ground plane layers and variation in the dopant concentrations in the various ground plane layers.

Although method 700 describes a process for fabricating the quantum processing device 600 of FIG. 6, it can be used to fabricate the quantum processing device 800 of FIG. 8. For instance, to fabricate the quantum processing device 800 of FIG. 8, the method step 706 is modified such that multiple layers of ground plane 804 are grown alternatively with layers of un-doped silicon 806.

The above embodiments describe structures to shield the qubit layer 103 from the charge noise of the interface. This allows the qubit layer to be fabricated closer to the interface 105 and the qubit layer 103 no longer needs to be buried deep in the semiconductor substrate (e.g., 100s of nanometers).

While this specification contains many specific details of the implementation, these should not limit the scope of any inventions or what may be claimed, but rather as descriptions to features specific to particular embodiments. Certain features described in this specification in the context of specific embodiments can also be implemented in a single embodiment. Conversely, various features that are described in context of a single embodiment can also be implemented in multiple embodiments separately or in any combination.

The foregoing description of the embodiments of the invention has been presented for the purpose of illustration; it is not intended to be exhaustive or to limit the invention to the precise forms disclosed. Persons skilled in the relevant art can appreciate that many modifications and variations are possible in light of the above disclosure.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based hereon. Accordingly, the disclosure of the embodiments of the invention is intended to be illustrative, but not limiting, of the scope of the invention, which is set forth in the following claims.

As used herein, except where the context requires otherwise, the term “comprise” and variations of the term, such as “comprising”, “comprises” and “comprised”, are not intended to exclude further additives, components, integers or steps.

1. A quantum processing device comprising:
a semiconductor substrate, comprising a bulk layer and a qubit layer;
one or more qubits formed in the qubit layer; and
a shielding structure formed between the bulk layer and the qubit layer, the shielding structure configured to shield the qubit layer from electric field generated in the bulk layer due to high-energy radiation.

2. The quantum processing device of claim 1, wherein the shielding structure further configured to recombine, absorb or extract electron-hole pairs created in the bulk layer due to high-energy radiation.

3. The quantum processing device of claim 1, wherein the shielding structure includes a single layer of an n-type semiconductor.

4. The quantum processing device of claim 3, wherein the n-type semiconductor is phosphorus doped silicon.

5. The quantum processing device of claim 4, wherein the concentration of phosphorus in the n-type semiconductor is between approximately 30% and 50%.

6. The quantum processing device of any one of claims 1-5, wherein the thickness of the shielding structure is in the range of 10 nanometers to 500 nanometers.

7. The quantum processing device of any one of claims 1-2, wherein the shielding structure comprises a plurality of layers of n-type semiconductor material interspersed with one or more spacer layers of an intrinsic silicon material.

8. The quantum processing device of claim 7, wherein the shielding structure comprises 2 to 50 layers of n-type semiconductor material.

9. The quantum processing device of claim 8, wherein the thickness of each shielding layer is about 10-500 nanometers.

10. The quantum processing device of any one of the preceding claims, wherein the shielding structure further comprises an electrode disposed at the bottom of the bulk layer, the electrode negatively charged to attract holes of the electron-hole pairs.

11. The quantum processing device of any one of claims 1-9, wherein the shielding structure further comprises a metal plate disposed at the bottom of the bulk layer to attract holes of the electron-hole pairs.

12. A method of fabricating a quantum processing device, comprising the following steps:
preparing a bulk layer of a semiconductor substrate;
preparing a clean crystal surface of the bulk layer;
exposing the clean crystal surface of the bulk layer to dopant molecules to produce a layer of dopant molecules on the exposed surface;
annealing the surface to incorporate at least some dopant atoms of the dopant molecules into the semiconductor and form a ground plane; and
preparing a qubit layer, the qubit layer formed of isotopically inert silicon and comprising a plurality of qubits.

13. The method of claim 12, wherein producing the ground plane further comprising:
preparing multiple layers of ground plane interspersed with one or more spacer layers of un-doped semiconductor.

14. The method of claim 12 or 13, wherein the ground plane is between the bulk layer and the qubit layer.

15. The method of any one of claims 12-14, wherein the ground plane is 1 atomic monolayer to 500 nanometers in thickness.

16. The method of any one of claims 12-15, wherein the dopant is any one of phosphorus or aluminum.

17. The method of any one of claims 12-16, wherein the concentration of dopant in the ground plane is approximately between 20% and 50%.

18. The method of any one of claims 12-17, further comprising the step of: adding a negatively charged electrode at the bottom of the bulk layer.

19. The method of any one of claims 12-17, further comprising the step of disposing a metal plate at the bottom of the bulk layer.

20. A quantum processor comprising:
a semiconductor substrate, comprising a qubit layer;
a dielectric material forming an interface with the semiconductor substrate;
one or more qubits formed in the qubit layer; and
a shielding structure formed between the interface and the qubit layer, the shielding structure configured to shield the qubit layer from charge noise generated in the interface between the dielectric material and the semiconductor substrate.

21. The quantum processor of claim 20, wherein the shielding structure includes a single layer of an n-type semiconductor.

22. The quantum processor of claim 21, wherein the n-type semiconductor is phosphorus doped silicon.

23. The quantum processor of claim 22, wherein the concentration of phosphorus in the n-type semiconductor is approximately 30% to 50%.

24. The quantum processor of any one of claims 20-23, wherein the thickness of the shielding structure is in the range of 10 nanometers to 500 nanometers.

25. The quantum processor of claim 20, wherein the shielding structure comprises a plurality of layers of n-type semiconductor material interspersed with one or more spacer layers of an intrinsic silicon material.

26. The quantum processor of claim 25, wherein the shielding structure comprises two to fifty layers of n-type semiconductor material.

27. The quantum processor of any one of claims 25-26, wherein the thickness of each shielding layer is about 10-500 nanometers.

28. A method of fabricating a quantum processing device, comprising the following steps:
preparing a bulk layer of a semiconductor substrate;
preparing a clean crystal surface of the bulk layer;
preparing a qubit layer, the qubit layer formed of isotopically inert silicon and comprising a plurality of qubits;
growing semiconductor layer above the qubit layer;
exposing the semiconductor layer to dopant molecules to produce a layer of dopant molecules on the exposed surface;
annealing the exposed surface to incorporate at least some dopant atoms of the dopant molecules into the semiconductor and form a ground plane.

29. The method of claim 28, wherein producing the ground plane further comprising:
preparing multiple layers of ground plane interspersed with one or more spacer layers of un-doped semiconductor.

30. The method of claim 28 or 29, wherein the ground plane is between the qubit layer and an interface formed between the semiconductor substrate and a dielectric.

31. The method of any one of claims 28-30, wherein the ground plane is 1 atomic monolayer to 500 nanometers in thickness.

32. The method of any one of claims 28-31, wherein the dopant is any one of phosphorus or aluminum.

33. The method of any one of claims 28-32, wherein the concentration of dopant in the ground plane is approximately between 20% and 50%.
